(19) United States
(12) Patent Application Publication
(10) Pub. No.: US 2018/0138081 A1
(43) Pub. Date: May 17, 2018

(54) SEMICONDUCTOR STRUCTURES AND METHOD FOR FABRICATING THE SAME

(71) Applicant: Vanguard International Semiconductor Corporation, Hsinchu (TW)

(72) Inventors: Shih-Kai WU, Hsinchu City (TW); Cheng-Yu WANG, Chiayi City (TW)

(73) Assignee: Vanguard International Semiconductor Corporation, Hsinchu (TW)

(21) Appl. No.: 15/352,125

(22) Filed: Nov. 15, 2016

(51) Int. Cl. H01L 21/762; H01L 23/48; H01L 21/768

(52) U.S. Cl. CPC H01L 21/76283; H01L 21/76898; H01L 23/481; H01L 21/76229

(57) ABSTRACT

A semiconductor structure is provided. The semiconductor structure includes a first substrate, an oxide layer formed on the first substrate, a second substrate formed on the oxide layer, a plurality of semiconductor devices formed in the second substrate, and a plurality of trenches formed in the second substrate and filled with an insulation material, wherein the trenches are separated from each other and one of the trenches surrounds one of the semiconductor devices. A method for fabricating a semiconductor structure is also provided.

### BACKGROUND OF THE INVENTION

### Field of the Invention

The invention relates to a semiconductor structure, and more particularly to a semiconductor structure with separate trenches and method for fabricating the same.

### Description of the Related Art

In current semiconductor processes, trenches are usually fabricated in a front end of line (FEOL) process. The FEOL includes various high-temperature processes, for example, each step in forming transistor devices. Therefore, when a single trench with a wide width is fabricated, and a single oxide material is filled into it, the result of thermal expansion and contraction caused by alternating between high and low temperatures usually results in dislocation defects forming in the structure and at the interface between the trenches and the substrate. This is due to the interaction of internal stresses, and can cause devices to suffer from problems such as current leakage.

In order to effectively control the influence of internal stress on an insulation structure in a silicon-on-insulator (SOI) structure and to avoid generating a large number of process defects, it is necessary to fill the existing trench pattern areas with a composite material. For the convenience of the trench pattern design, formation of cross intersections in the trench patterns is permitted. However, if the cross intersection areas of the trenches are not filled and flattened, when subsequent metal interconnections cross the intersections, a cross-line short-circuit is likely to be formed. Therefore, use of thicker composite material and a chemical mechanical polishing (CMP) treatment are required to completely fill the trenches, resulting in an increase in the overall cost.

Additionally, in order to comply with the application requirements of some circuit designs, a buried oxide (BOX) of a silicon-on-insulator (SOI) is opened if necessary. Upper and lower silicon substrates are connected to form the so-called top-side contact (TSC) and various voltages are applied thereon to change or stabilize the characteristics of the devices. However, the existing trench design merely provides an insulating function between devices.

Therefore, development of a semiconductor structure capable of solving the problem of cross-line short-circuits caused by cross intersection of trenches, having an appropriate insulation effect and maintaining the stability of the electrical properties of devices under the conditions of applying certain low or high voltage, is the direction that the industry's ongoing efforts should take.

### BRIEF SUMMARY OF THE INVENTION

One embodiment of the invention provides a semiconductor structure comprising a first substrate; an oxide layer formed on the first substrate; a second substrate formed on the oxide layer; a plurality of semiconductor devices formed in the second substrate; and a plurality of trenches formed in the second substrate and filled with an insulation material, wherein the trenches are separated from each other and one of the trenches surrounds one of the semiconductor devices.

One embodiment of the invention provides a semiconductor structure comprising a first substrate; an oxide layer formed on the first substrate; a second substrate formed on the oxide layer; a plurality of semiconductor devices formed in the second substrate; a plurality of first trenches; a contact window; and a third trench. The first trenches are formed in the second substrate and are filled with an insulation material, and the first trenches are separated from each other. One of the first trenches surrounds one of the semiconductor devices. The contact window is formed in the second substrate and extends through the oxide layer. The contact window is connected to the first substrate and is filled with a conductive material. The third trench is formed in the second substrate and is filled with the insulation material. The third trench surrounds the contact window.

One embodiment of the invention provides a method for fabricating a semiconductor structure comprising providing a silicon-on-insulator (SOI) structure comprising a first silicon substrate, an oxide layer and a second silicon substrate, wherein the oxide layer is formed on the first silicon substrate and the second silicon substrate is formed on the oxide layer; forming a plurality of first trenches, a second trench having sidewalls and a bottom and a third trench in the second silicon substrate, wherein the first trenches are separated from each other and the third trench surrounds the second trench; forming an insulation material on the second silicon substrate to fill the first trenches and the third trench and a part of the second trench; etching the second trench using the insulation material as a mask to extend through the oxide layer to connect to the first silicon substrate; and filling a conductive material in the second trench to electrically connect to the first silicon substrate.

In order to take into account the reduced influence of internal stress of the trench structures and to avoid forming recessed areas at the intersections of trench patterns, a novel trench pattern (wherein the trenches surrounding the semiconductor devices are separated from each other without intersecting, as shown in FIG. 1A) is designed in the invention. The amount and thickness of the material used for filling the trenches are reduced by decreasing the width of the trenches, replacing the conventional composite material for filling the trenches with the silicon substrate, and only filling the single insulation material such as oxides in the trenches, without formation of cross intersection areas of the deep trenches, and there is no need for a further increase in the amount and thickness of the filling material. The amount of polishing done during chemical mechanical polishing (CMP) is reduced due to the decline in the overall thickness, thereby improving the uniformity of thickness after polishing.

In order to connect the upper and lower silicon substrates on the two sides of the buried oxide (BOX) of the silicon-on-insulator (SOI) to form the top-side contact window (TSC), in the invention, the design of the trench patterns whose wide and narrow widths coexist is adopted. The top-side contact window (TSC) has a wide width, and the ring trenches with a narrow width serve as insulation protection. The destination for increasing the number of ring trenches is to require sufficient insulation protection to avoid direct interaction between the top-side contact window (TSC) and the semiconductor device area while a specific voltage (a low voltage or a high voltage) is applied to the top-side contact window (TSC) rather than under a grounding mode. The advantage of defining wide and narrow trenches at the same time is that one trench-etching process is eliminated. After the single material is filled into narrow-width trenches, the wide-width trench is etched using the existing hard mask as a protection layer. Next, the conductive material is conducted to the wide-width trench to form the top-side contact window (TSC).

Additionally, the invention adopts a design for trench patterns whose wide and narrow widths coexist to define wide and narrow trenches at the same time. After the single material is filled into the narrow-width trenches, the location of the wide-width trench to be etched is defined using a mask, and then the wide-width trench is etched using a photoresist as a barrier. The narrow-width trenches are capable of avoiding exposure under the photoresist protection. Next, the conductive material is conducted to the wide-width trench to form the top-side contact window (TSC).

A detailed description is given in the following embodiments with reference to the accompanying drawings.

### BRIEF DESCRIPTION OF THE DRAWINGS

The present invention can be more fully understood by reading the subsequent detailed description and examples with references made to the accompanying drawings, wherein:

FIG. 1A is a top view of a semiconductor structure in accordance with one embodiment of the invention;

FIG. 1B is a cross-sectional view of the semiconductor structure along a cross-sectional line A-A′ of FIG. 1A;

FIG. 2A is a top view of a semiconductor structure in accordance with one embodiment of the invention;

FIG. 2B is a cross-sectional view of the semiconductor structure along a cross-sectional line A-A′ of FIG. 2A;

FIG. 3A is a top view of a semiconductor structure in accordance with one embodiment of the invention;

FIG. 3B is a cross-sectional view of the semiconductor structure along a cross-sectional line A-A′ of FIG. 3A;

FIG. 4A is a top view of a semiconductor structure in accordance with one embodiment of the invention;

FIG. 4B is a cross-sectional view of the semiconductor structure along a cross-sectional line A-A′ of FIG. 4A;

FIGS. 5A-5D are cross-sectional views of a method for fabricating a semiconductor structure in accordance with one embodiment of the invention; and

FIGS. 6A-6D are cross-sectional views of a method for fabricating a semiconductor structure in accordance with one embodiment of the invention.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

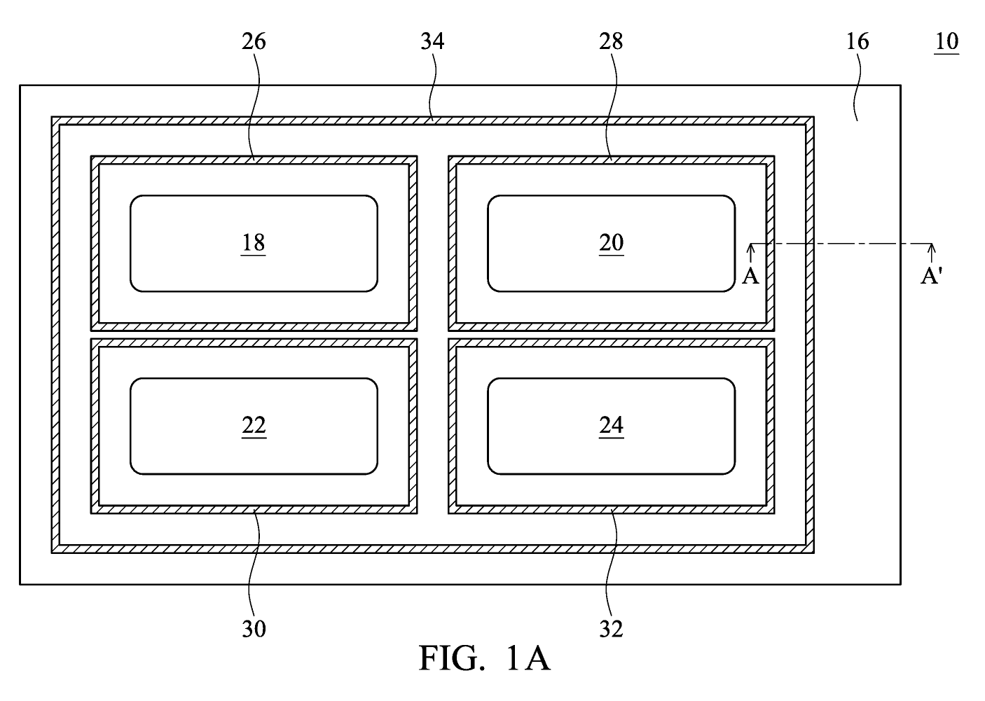

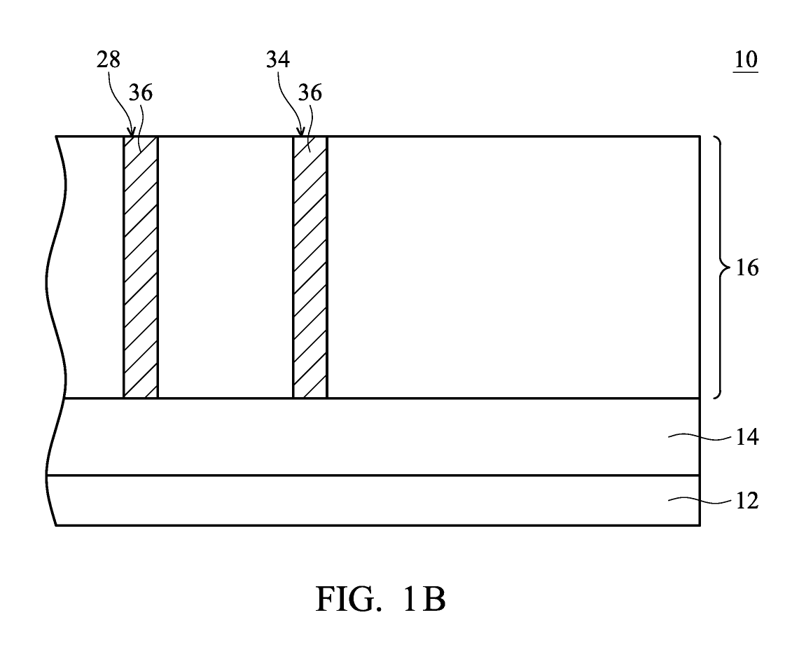

Referring to FIGS. 1A and 1B, in accordance with one embodiment of the invention, a semiconductor structure 10 is provided. FIG. 1A is a top view of the semiconductor structure 10. FIG. 1B is a cross-sectional view of the semiconductor structure 10 along a cross-sectional line A-A′ of FIG. 1A.

As shown in FIGS. 1A and 1B, in this embodiment, the semiconductor structure 10 comprises a first substrate 12, an oxide layer 14, a second substrate 16, a plurality of semiconductor devices (18, 20, 22 and 24), and a plurality of trenches (26, 28, 30, 32 and 34). The oxide layer 14 is formed on the first substrate 12. The second substrate 16 is formed on the oxide layer 14. The semiconductor devices (18, 20, 22 and 24) are formed in the second substrate 16. The trenches (26, 28, 30, 32 and 34) are formed in the second substrate 16 and filled with an insulation material 36. Specifically, the trenches (26, 28, 30, 32 and 34) are separated from each other and one of the trenches (26, 28, 30 and 32) surrounds one of the semiconductor devices (18, 20, 22 and 24). That is, each of the semiconductor devices is surrounded by one trench. For example, the trench 26 surrounds the semiconductor device 18, the trench 28 surrounds the semiconductor device 20, the trench 30 surrounds the semiconductor device 22, and the trench 32 surrounds the semiconductor device 24, as shown in FIG. 1A.

In some embodiments, the first substrate 12 and the second substrate 16 may be silicon substrates such that the semiconductor structure 10 is formed into a silicon-on-insulator (SOI) structure.

In some embodiments, the semiconductor devices (18, 20, 22 and 24) may comprise various high-voltage or low-voltage devices, including, but not limited to, field-effect transistors (FETs) or bipolar junction transistors (BJTs).

In some embodiments, the trenches (26, 28, 30, 32 and 34) have widths of about 0.6-1.0 μm.

In some embodiments, the trenches (26, 28, 30, 32 and 34) are only filled with the insulation material 36.

In some embodiments, the insulation material 36 may comprise various suitable metal oxides.

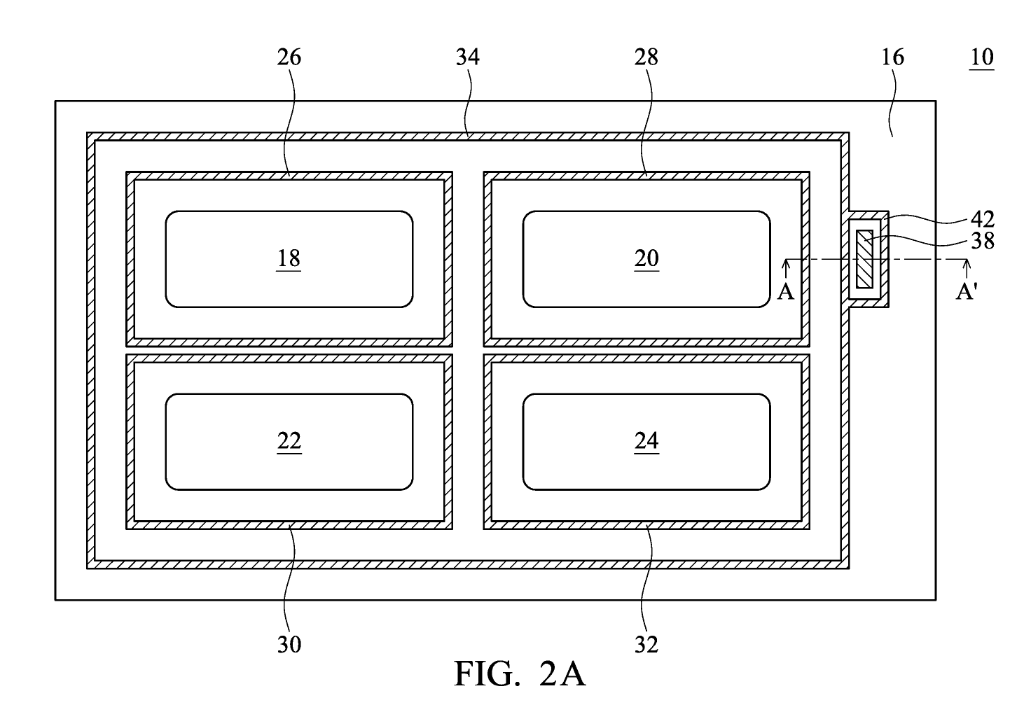

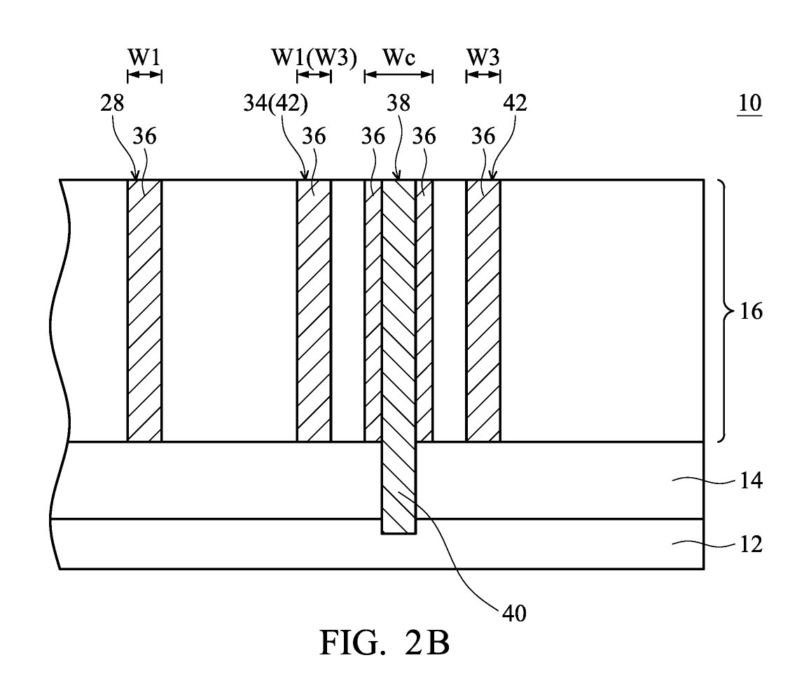

Referring to FIGS. 2A and 2B, in accordance with one embodiment of the invention, a semiconductor structure 10 is provided. FIG. 2A is a top view of the semiconductor structure 10. FIG. 2B is a cross-sectional view of the semiconductor structure 10 along a cross-sectional line A-A′ of FIG. 2A.

As shown in FIGS. 2A and 2B, in this embodiment, the semiconductor structure 10 comprises a first substrate 12, an oxide layer 14, a second substrate 16, a plurality of semiconductor devices (18, 20, 22 and 24), a plurality of first trenches (26, 28, 30, 32 and 34), a contact window 38, and a third trench 42. The oxide layer 14 is formed on the first substrate 12. The second substrate 16 is formed on the oxide layer 14. The semiconductor devices (18, 20, 22 and 24) are formed in the second substrate 16. The first trenches (26, 28, 30, 32 and 34) are formed in the second substrate 16 and filled with an insulation material 36. Specifically, the first trenches (26, 28, 30, 32 and 34) are separated from each other and one of the first trenches (26, 28, 30 and 32) surrounds one of the semiconductor devices (18, 20, 22 and 24). That is, each of the semiconductor devices is surrounded by one trench. For example, the first trench 26 surrounds the semiconductor device 18, the first trench 28 surrounds the semiconductor device 20, the first trench 30 surrounds the semiconductor device 22, and the first trench 32 surrounds the semiconductor device 24, as shown in FIG. 2A.

Additionally, the contact window 38 is formed in the second substrate 16 and extended through the oxide layer 14 to connect to the first substrate 12. The contact window 38 is filled with a conductive material 40. The third trench 42 is formed in the second substrate 16 and filled with the insulation material 36. Specifically, the third trench 42 surrounds the contact window 38.

In some embodiments, the first substrate 12 and the second substrate 16 may be silicon substrates such that the semiconductor structure 10 is formed into a silicon-on-insulator (SOI) structure.

In some embodiments, the semiconductor devices (18, 20, 22 and 24) may comprise various high-voltage or low-voltage devices, including, but not limited to, field-effect transistors (FETs) or bipolar junction transistors (BJTs).

In some embodiments, the first trenches (26, 28, 30, 32 and 34) have widths W1 of about 0.6-1.0 μm. The third trench 42 has a width W3 of about 0.6-1.0 μm.

In some embodiments, the first trenches (26, 28, 30, 32 and 34) and the third trench 42 are only filled with the insulation material 36.

In some embodiments, the insulation material 36 may comprise various suitable metal oxides.

In some embodiments, the contact window 38 has a width Wc that is larger than the width W1 of the first trenches (26, 28, 30, 32 and 34) and larger than the width W3 of the third trench 42.

In some embodiments, the width Wc of the contact window 38 is about 2.0 μm.

In some embodiments, the width W1 of the first trenches (26, 28, 30, 32 and 34) is the same as the width W3 of the third trench 42.

In some embodiments, the conductive material 40 may comprise various suitable metal materials.

In this embodiment, the contact window 38 is a top-side contact (TSC).

In this embodiment, the first trenches (26, 28, 30, 32 and 34) partially overlap the third trench 42. For example, the first trench 34 overlaps one side of the third trench 42, as shown in FIG. 2A.

In this embodiment, when a specific low voltage is applied to the contact window 38, a semiconductor device zone (i.e. the zone including the semiconductor devices (18, 20, 22 and 24)) acquires sufficient insulation protection through disposition of the first trenches (26, 28, 30, 32 and 34) and the third trench 42.

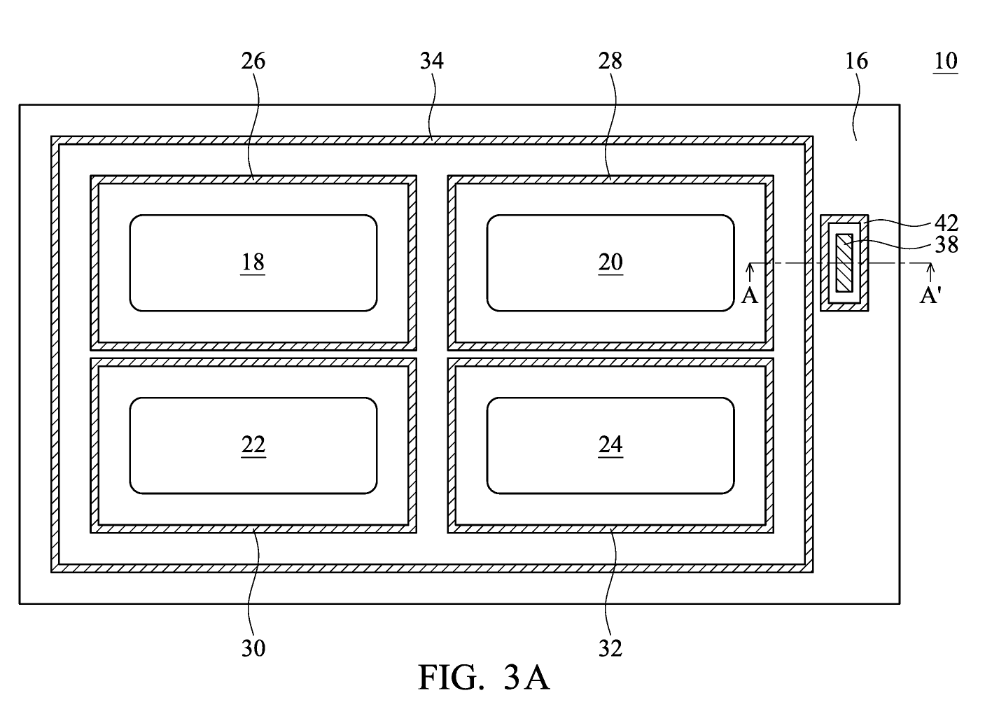

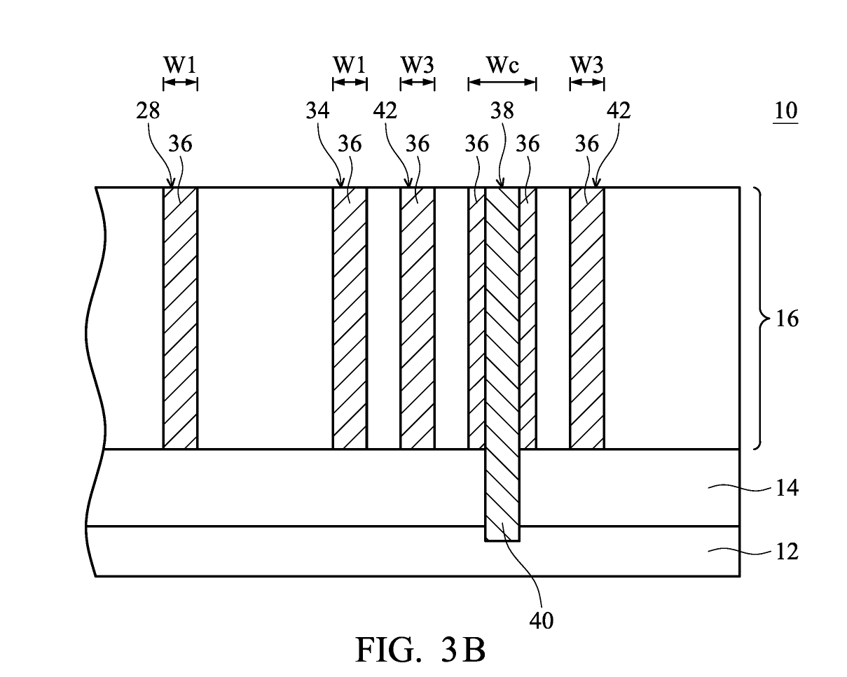

Referring to FIGS. 3A and 3B, in accordance with one embodiment of the invention, a semiconductor structure 10 is provided. FIG. 3A is a top view of the semiconductor structure 10. FIG. 3B is a cross-sectional view of the semiconductor structure 10 along a cross-sectional line A-A′ of FIG. 3A.

As shown in FIGS. 3A and 3B, in this embodiment, the semiconductor structure 10 comprises a first substrate 12, an oxide layer 14, a second substrate 16, a plurality of semiconductor devices (18, 20, 22 and 24), a plurality of first trenches (26, 28, 30, 32 and 34), a contact window 38, and a third trench 42. The oxide layer 14 is formed on the first substrate 12. The second substrate 16 is formed on the oxide layer 14. The semiconductor devices (18, 20, 22 and 24) are formed in the second substrate 16. The first trenches (26, 28, 30, 32 and 34) are formed in the second substrate 16 and filled with an insulation material 36. Specifically, the first trenches (26, 28, 30, 32 and 34) are separated from each other and one of the first trenches (26, 28, 30 and 32) surrounds one of the semiconductor devices (18, 20, 22 and 24). That is, each of the semiconductor devices is surrounded by one trench. For example, the first trench 26 surrounds the semiconductor device 18, the first trench 28 surrounds the semiconductor device 20, the first trench 30 surrounds the semiconductor device 22, and the first trench 32 surrounds the semiconductor device 24, as shown in FIG. 3A.

Additionally, the contact window 38 is formed in the second substrate 16 and extended through the oxide layer 14 to connect to the first substrate 12. The contact window 38 is filled with a conductive material 40. The third trench 42 is formed in the second substrate 16 and filled with the insulation material 36. Specifically, the third trench 42 surrounds the contact window 38.

In some embodiments, the first substrate 12 and the second substrate 16 may be silicon substrates such that the semiconductor structure 10 is formed into a silicon-on-insulator (SOI) structure.

In some embodiments, the semiconductor devices (18, 20, 22 and 24) may comprise various high-voltage or low-voltage devices, including, but not limited to, field-effect transistors (FETs) or bipolar junction transistors (BJTs).

In some embodiments, the first trenches (26, 28, 30, 32 and 34) have widths W1 of about 0.6-1.0 μm. The third trench 42 has a width W3 of about 0.6-1.0 μm.

In some embodiments, the first trenches (26, 28, 30, 32 and 34) and the third trench 42 are only filled with the insulation material 36.

In some embodiments, the insulation material 36 may comprise various suitable metal oxides.

In some embodiments, the contact window 38 has a width Wc that is larger than the width W1 of the first trenches (26, 28, 30, 32 and 34) and larger than the width W3 of the third trench 42.

In some embodiments, the width Wc of the contact window 38 is about 2.0 μm.

In some embodiments, the width W1 of the first trenches (26, 28, 30, 32 and 34) is the same as the width W3 of the third trench 42.

In some embodiments, the conductive material 40 may comprise various suitable metal materials.

In this embodiment, the contact window 38 is a top-side contact (TSC).

In this embodiment, the first trenches (26, 28, 30, 32 and 34) are separated from the third trench 42. For example, the first trench 34 does not overlap any one side of the third trench 42, as shown in FIG. 3A.

In this embodiment, when a specific high voltage is applied to the contact window 38, a semiconductor device zone (i.e. the zone including the semiconductor devices (18, 20, 22 and 24)) acquires sufficient insulation protection through disposition of the first trenches (26, 28, 30, 32 and 34) and the third trench 42.

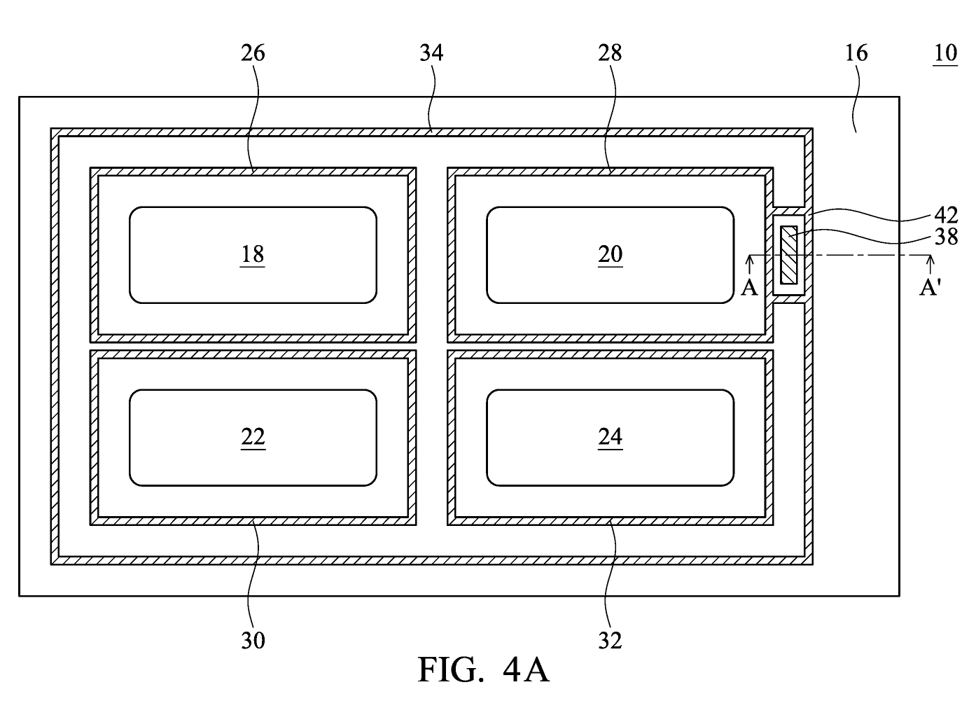

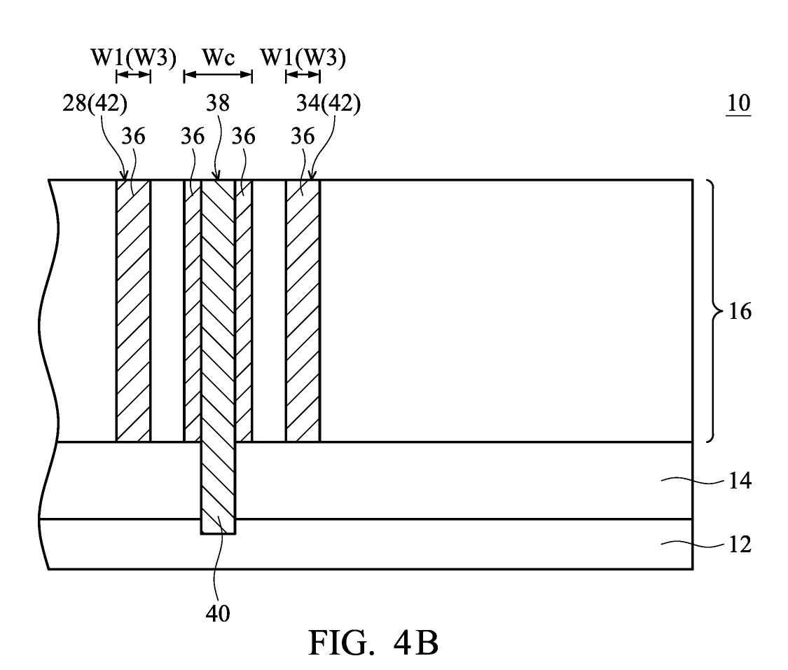

Referring to FIGS. 4A and 4B, in accordance with one embodiment of the invention, a semiconductor structure 10 is provided. FIG. 4A is a top view of the semiconductor structure 10. FIG. 4B is a cross-sectional view of the semiconductor structure 10 along a cross-sectional line A-A′ of FIG. 4A.

As shown in FIGS. 4A and 4B, in this embodiment, the semiconductor structure 10 comprises a first substrate 12, an oxide layer 14, a second substrate 16, a plurality of semiconductor devices (18, 20, 22 and 24), a plurality of first trenches (26, 28, 30, 32 and 34), a contact window 38, and a third trench 42. The oxide layer 14 is formed on the first substrate 12. The second substrate 16 is formed on the oxide layer 14. The semiconductor devices (18, 20, 22 and 24) are formed in the second substrate 16. The first trenches (26, 28, 30, 32 and 34) are formed in the second substrate 16 and filled with an insulation material 36. Specifically, the first trenches (26, 28, 30, 32 and 34) are separated from each other and one of the first trenches (26, 28, 30 and 32) surrounds one of the semiconductor devices (18, 20, 22 and 24). That is, each of the semiconductor devices is surrounded by one trench. For example, the first trench 26 surrounds the semiconductor device 18, the first trench 28 surrounds the semiconductor device 20, the first trench 30 surrounds the semiconductor device 22, and the first trench 32 surrounds the semiconductor device 24, as shown in FIG. 4A.

Additionally, the contact window 38 is formed in the second substrate 16 and extended through the oxide layer 14 to connect to the first substrate 12. The contact window 38 is filled with a conductive material 40. The third trench 42 is formed in the second substrate 16 and filled with the insulation material 36. Specifically, the third trench 42 surrounds the contact window 38.

In some embodiments, the first substrate 12 and the second substrate 16 may be silicon substrates such that the semiconductor structure 10 is formed into a silicon-on-insulator (SOI) structure.

In some embodiments, the semiconductor devices (18, 20, 22 and 24) may comprise various high-voltage or low-voltage devices, including, but not limited to, field-effect transistors (FETs) or bipolar junction transistors (BJTs).

In some embodiments, the first trenches (26, 28, 30, 32 and 34) have widths W1 of about 0.6-1.0 μm. The third trench 42 has a width W3 of about 0.6-1.0 μm.

In some embodiments, the first trenches (26, 28, 30, 32 and 34) and the third trench 42 are only filled with the insulation material 36.

In some embodiments, the insulation material 36 may comprise various suitable metal oxides.

In some embodiments, the contact window 38 has a width Wc that is larger than the width W1 of the first trenches (26, 28, 30, 32 and 34) and larger than the width W3 of the third trench 42.

In some embodiments, the width Wc of the contact window 38 is about 2.0 μm.

In some embodiments, the width W1 of the first trenches (26, 28, 30, 32 and 34) is the same as the width W3 of the third trench 42.

In some embodiments, the conductive material 40 may comprise various suitable metal materials.

In this embodiment, the first trenches (26, 28, 30, 32 and 34) partially overlap the third trench 42. For example, the first trenches (28 and 34) overlap two sides of the third trench 42, as shown in FIG. 4A.

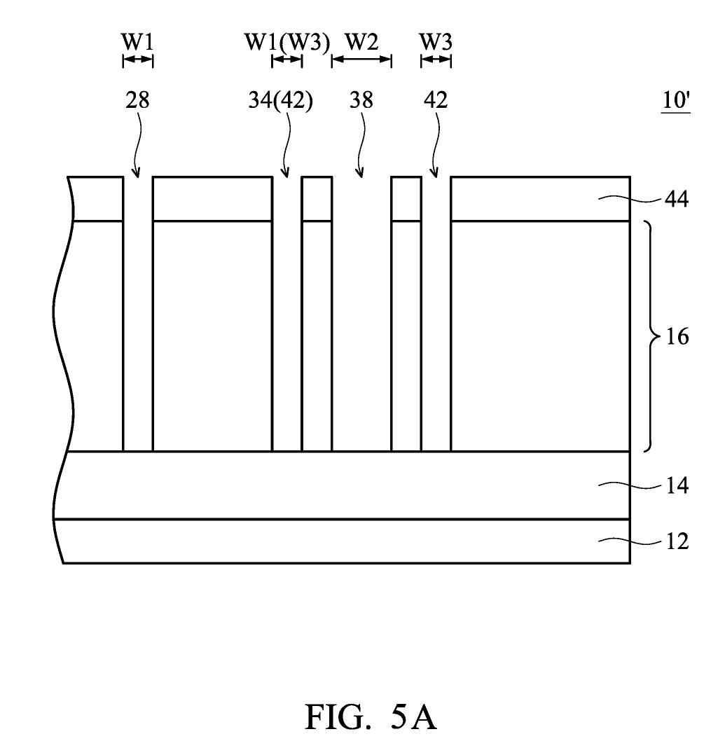

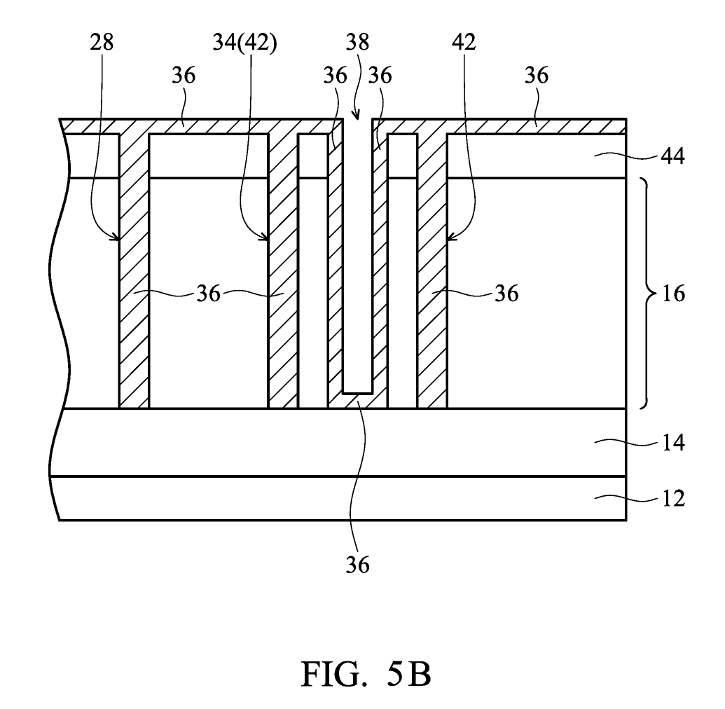

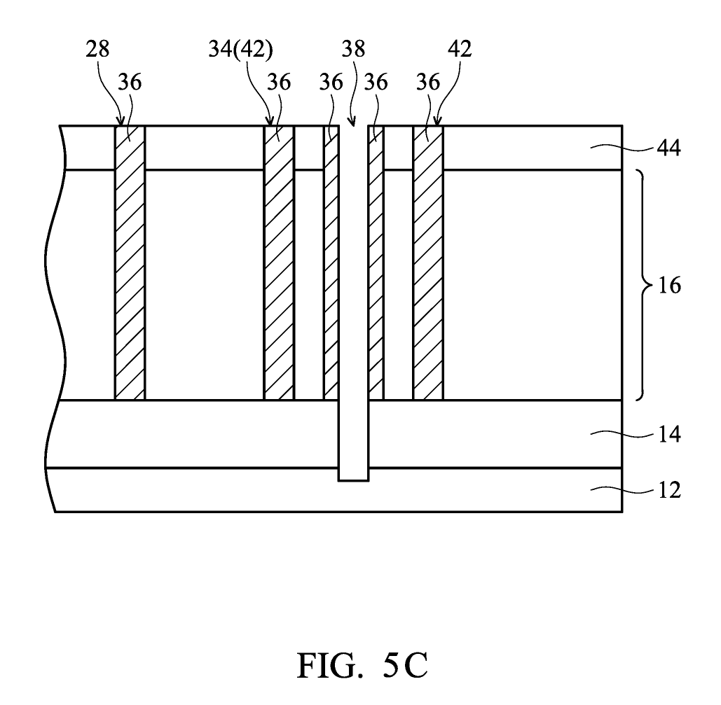

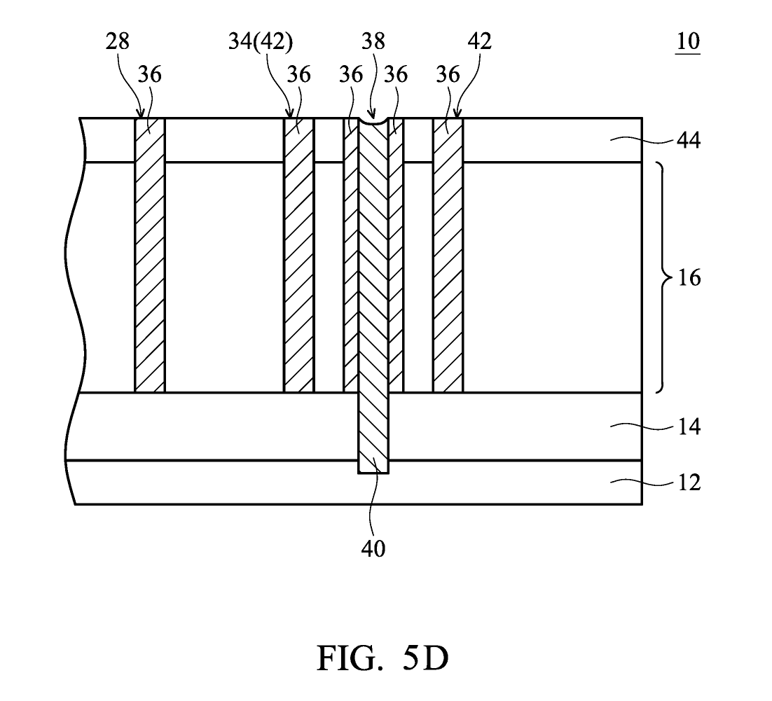

Referring to FIGS. 2A-2B and 5A-5D, in accordance with one embodiment of the invention, a method for fabricating the semiconductor structure 10 (as shown in FIGS. 2A and 2B) is provided. FIGS. 5A-5D are cross-sectional views of the method for fabricating the semiconductor structure 10.

Referring to FIG. 5A, a silicon-on-insulator (SOI) structure 10′ is provided.

As shown in FIG. 5A, the silicon-on-insulator (SOI) structure 10′ comprises a first silicon substrate 12, an oxide layer 14 and a second silicon substrate 16. The oxide layer 14 is formed on the first silicon substrate 12. The second silicon substrate 16 is formed on the oxide layer 14.

A patterned hard mask film 44 is formed on the second silicon substrate 16.

In some embodiments, the patterned hard mask film 44 is formed on the second silicon substrate 16 by, for example, chemical vapor deposition (CVD) or physical vapor deposition (PVD) and a patterning process.

In some embodiments, the patterned hard mask film 44 may comprise, but is not limited to, silicon oxide (SiO), silicon nitride (SiN) , silicon carbide (SiC), silicon oxide nitride (SiON), silicon carbide nitride (SiCN), silicon oxide carbide nitride (SiOCN), tantalum (Ta), tantalum nitride (TaN), titanium (Ti), titanium nitride (TiN), aluminum oxide (Al₂O₃), boron nitride (BN), hydrogen silsesquioxane (HSQ) or another suitable material with high etch selectivity.

The second silicon substrate 16 is etched through the patterned hard mask film 44 to form a plurality of first trenches (26, 28, 30, 32 and 34), a second trench 38 and a third trench 42 in the second silicon substrate 16. Specifically, the first trenches (26, 28, 30, 32 and 34) are separated from each other and the third trench 42 surrounds the second trench 38.

In some embodiments, the first trenches (26, 28, 30, 32 and 34) have widths W1 of about 0.6-1.0 μm. The third trench 42 has a width W3 of about 0.6-1.0 μm.

In some embodiments, the second trench 38 has a width W2 that is larger than the width W1 of the first trenches (26, 28, 30, 32 and 34) and larger than the width W3 of the third trench 42.

In some embodiments, the width W2 of the second trench 38 is about 2.0 μm.

In some embodiments, the width W1 of the first trenches (26, 28, 30, 32 and 34) is the same as the width W3 of the third trench 42.

In this embodiment, the first trenches (26, 28, 30, 32 and 34) partially overlap the third trench 42. For example, the first trench 34 overlaps one side of the third trench 42, as shown in FIG. 2A.

In other embodiments, the first trenches (26, 28, 30, 32 and 34) may be separated from the third trench 42. For example, the first trench 34 does not overlap any one side of the third trench 42, as shown in FIG. 3A.

Referring to FIG. 5B, an insulation material 36 is formed on the second silicon substrate 16 to fill the first trenches (26, 28, 30, 32 and 34), the third trench 42 and a part of the second trench 38, for example, the insulation material 36 filling the sidewalls and bottom of the second trench 38.

In some embodiments, the insulation material 36 is formed on the second silicon substrate 16 to fill the first trenches (26, 28, 30, 32 and 34), the third trench 42 and a part of the second trench 38 by, for example, chemical vapor deposition (CVD) or physical vapor deposition (PVD).

In some embodiments, the first trenches (26, 28, 30, 32 and 34) and the third trench 42 are only filled with the insulation material 36.

In some embodiments, the insulation material 36 may comprise various suitable dielectric materials, for example, barium strontium titanate (BST) or metal oxides such as silicon dioxide.

Referring to FIG. 5C, the second trench 38 is etched using the insulation material 36 as a mask to make the second trench 38 extend through the oxide layer 14 to connect to the first silicon substrate 12.

Referring to FIG. 5D, a conductive material 40 is filled in the second trench 38 to form a contact window 38 to electrically connect to the first silicon substrate 12.

In some embodiments, the conductive material 40 is filled in the second trench 38 by, for example, chemical vapor deposition (CVD) or physical vapor deposition (PVD) and an etch-back process.

In some embodiments, the conductive material 40 may comprise various suitable metal materials.

In this embodiment, the contact window 38 is a top-side contact (TSC).

From this, the fabrication of the semiconductor structure 10 (as shown in FIGS. 2A and 2B) is completed.

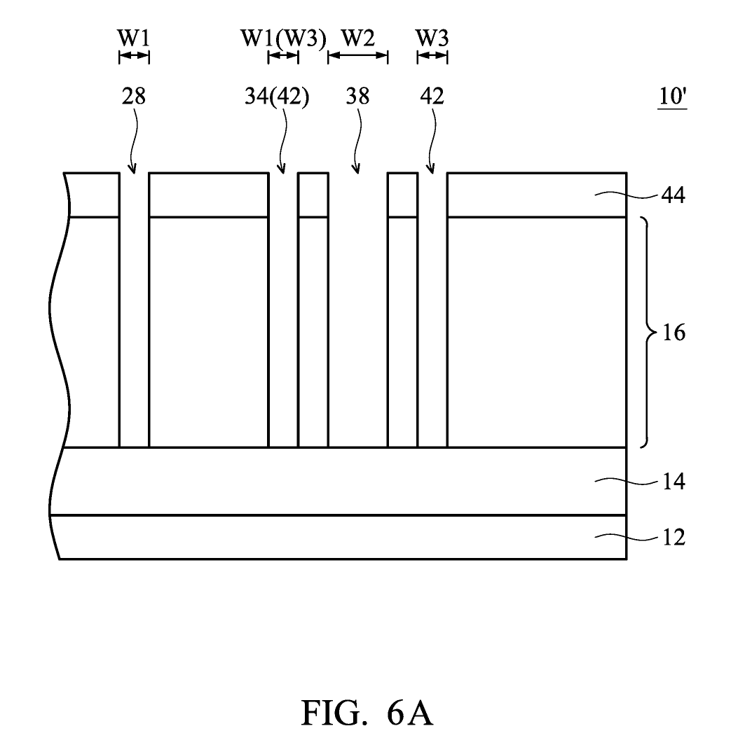

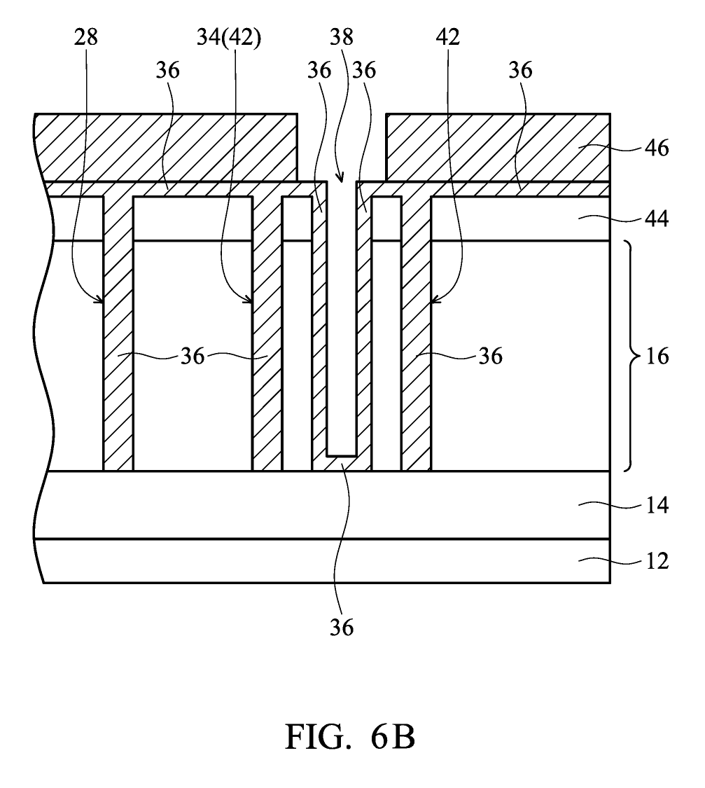

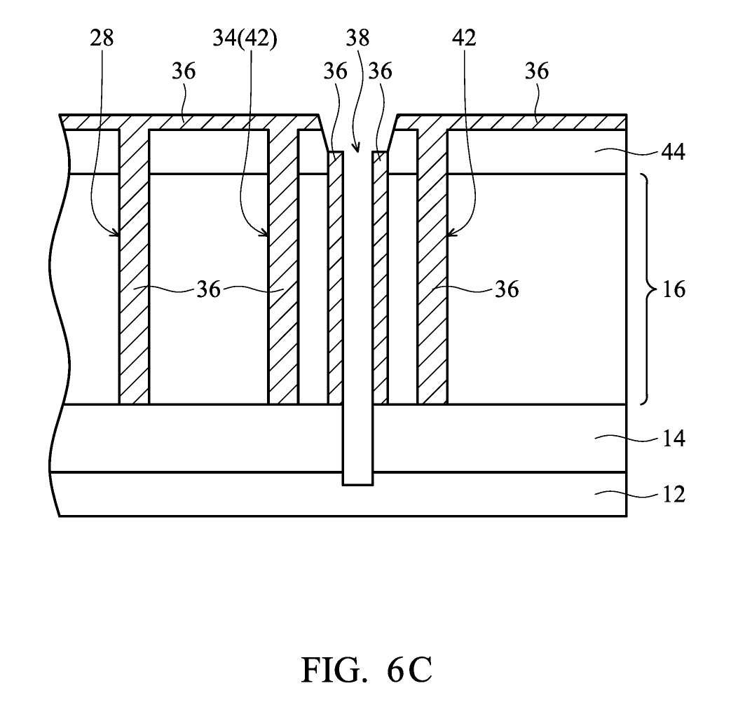

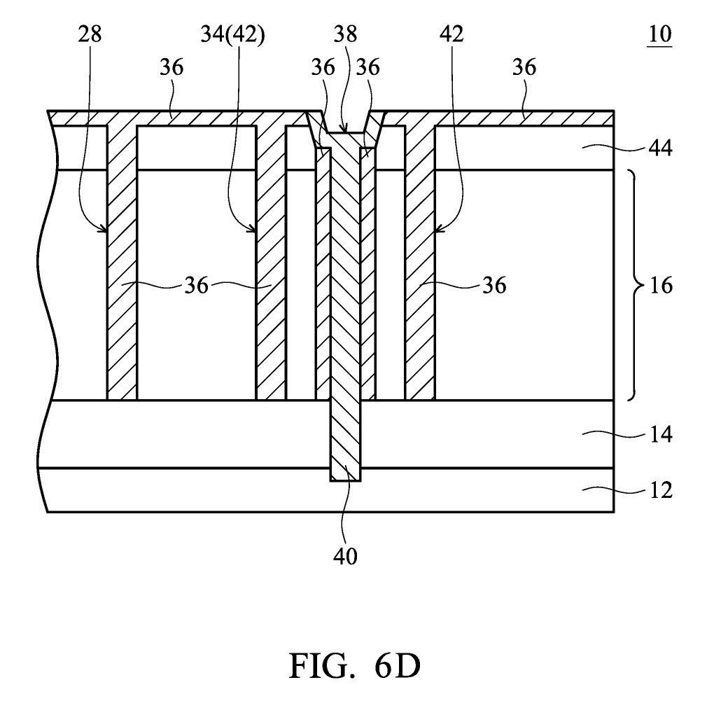

Referring to FIGS. 2A-2B and 6A-6D, in accordance with one embodiment of the invention, a method for fabricating the semiconductor structure 10 (as shown in FIGS. 2A and 2B) is provided. FIGS. 6A-6D are cross-sectional views of the method for fabricating the semiconductor structure 10.

Referring to FIG. 6A, a silicon-on-insulator (SOI) structure 10′ is provided.

As shown in FIG. 6A, the silicon-on-insulator (SOI) structure 10′ comprises a first silicon substrate 12, an oxide layer 14 and a second silicon substrate 16. The oxide layer 14 is formed on the first silicon substrate 12. The second silicon substrate 16 is formed on the oxide layer 14.

A patterned hard mask film 44 is formed on the second silicon substrate 16.

In some embodiments, the patterned hard mask film 44 is formed on the second silicon substrate 16 by, for example, chemical vapor deposition (CVD) or physical vapor deposition (PVD) and a patterning process.

In some embodiments, the patterned hard mask film 44 may comprise, but is not limited to, silicon oxide (SiO), silicon nitride (SiN) , silicon carbide (SiC), silicon oxide nitride (SiON), silicon carbide nitride (SiCN), silicon oxide carbide nitride (SiOCN), tantalum (Ta), tantalum nitride (TaN), titanium (Ti), titanium nitride (TiN), aluminum oxide (Al₂O₃), boron nitride (BN), hydrogen silsesquioxane (HSQ) or another suitable material with high etch selectivity.

The second silicon substrate 16 is etched through the patterned hard mask film 44 to form a plurality of first trenches (26, 28, 30, 32 and 34), a second trench 38 and a third trench 42 in the second silicon substrate 16. Specifically, the first trenches (26, 28, 30, 32 and 34) are separated from each other and the third trench 42 surrounds the second trench 38.

In some embodiments, the first trenches (26, 28, 30, 32 and 34) have widths W1 of about 0.6-1.0 μm. The third trench 42 has a width W3 of about 0.6-1.0 μm.

In some embodiments, the second trench 38 has a width W2 that is larger than the width W1 of the first trenches (26, 28, 30, 32 and 34) and larger than the width W3 of the third trench 42.

In some embodiments, the width W2 of the second trench 38 is about 2.0 μm.

In some embodiments, the width W1 of the first trenches (26, 28, 30, 32 and 34) is the same as the width W3 of the third trench 42.

In this embodiment, the first trenches (26, 28, 30, 32 and 34) partially overlap the third trench 42. For example, the first trench 34 overlaps one side of the third trench 42, as shown in FIG. 2A.

In other embodiments, the first trenches (26, 28, 30, 32 and 34) may be separated from the third trench 42. For example, the first trench 34 does not overlap any one side of the third trench 42, as shown in FIG. 3A.

Referring to FIG. 6B, an insulation material 36 is formed on the second silicon substrate 16 to fill the first trenches (26, 28, 30, 32 and 34), the third trench 42 and a part of the second trench 38, for example, the insulation material 36 filling the sidewalls and bottom of the second trench 38.

In some embodiments, the insulation material 36 is formed on the second silicon substrate 16 to fill the first trenches (26, 28, 30, 32 and 34), the third trench 42 and a part of the second trench 38 by, for example, chemical vapor deposition (CVD) or physical vapor deposition (PVD).

In some embodiments, the first trenches (26, 28, 30, 32 and 34) and the third trench 42 are only filled with the insulation material 36.

In some embodiments, the insulation material 36 may comprise various suitable dielectric materials, for example, barium strontium titanate (BST) or metal oxides such as silicon dioxide.

A patterned photoresist layer 46 is formed on the insulation material 36, exposing the second trench 38.

In some embodiments, the patterned photoresist layer 46 is formed on the insulation material 36 by, for example, a coating process and a patterning process.

Referring to FIG. 6C, the second trench 38 is etched using the patterned photoresist layer 46 as a mask to make the second trench 38 extend through the oxide layer 14 to connect to the first silicon substrate 12.

The remaining patterned photoresist layer 46 is removed, exposing the insulation material 36 on the second silicon substrate 16.

Referring to FIG. 6D, a conductive material 40 is filled in the second trench 38 to form a contact window 38 to electrically connect to the first silicon substrate 12.

In some embodiments, the conductive material 40 is filled in the second trench 38 by, for example, chemical vapor deposition (CVD) or physical vapor deposition (PVD) and an etch-back process.

In some embodiments, the conductive material 40 may comprise various suitable metal materials.

In this embodiment, the contact window 38 is a top-side contact (TSC).

From this, the fabrication of the semiconductor structure 10 (as shown in FIGS. 2A and 2B) is completed.

In order to take into account the reduced influence of internal stress of the trench structures and to avoid forming recessed areas at the intersections of trench patterns, a novel trench pattern (wherein the trenches surrounding the semiconductor devices are separated from each other without intersecting, as shown in FIG. 1A) is designed in the invention. The amount and thickness of the material used for filling the trenches are reduced by decreasing the width of the trenches, replacing the conventional composite material for filling the trenches with the silicon substrate, and only filling the single insulation material such as oxides in the trenches, without formation of cross intersection areas of the deep trenches, and there is no need for a further increase in the amount and thickness of the filling material. The amount of polishing done during chemical mechanical polishing (CMP) is reduced due to the decline in the overall thickness, thereby improving the uniformity of thickness after polishing.

In order to connect the upper and lower silicon substrates on the two sides of the buried oxide (BOX) of the silicon-on-insulator (SOI) to form the top-side contact window (TSC), in the invention, the design of the trench patterns whose wide and narrow widths coexist is adopted. The top-side contact window (TSC) has a wide width, and the ring trenches with a narrow width serve as insulation protection. The destination for increasing the number of ring trenches is to require sufficient insulation protection to avoid direct interaction between the top-side contact window (TSC) and the semiconductor device area while a specific voltage (a low voltage or a high voltage) is applied to the top-side contact window (TSC) rather than under a grounding mode. The advantage of defining wide and narrow trenches at the same time is that one trench-etching process is eliminated. After the single material is filled into narrow-width trenches, the wide-width trench is etched using the existing hard mask as a protection layer. Next, the conductive material is conducted to the wide-width trench to form the top-side contact window (TSC).

Additionally, the invention adopts a design for trench patterns whose wide and narrow widths coexist to define wide and narrow trenches at the same time. After the single material is filled into the narrow-width trenches, the location of the wide-width trench to be etched is defined using a mask, and then the wide-width trench is etched using a photoresist as a barrier. The narrow-width trenches are capable of avoiding exposure under the photoresist protection. Next, the conductive material is conducted to the wide-width trench to form the top-side contact window (TSC).

While the invention has been described by way of example and in terms of preferred embodiment, it is to be understood that the invention is not limited thereto. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A semiconductor structure, comprising:
a first substrate;
an oxide layer formed on the first substrate;
a second substrate formed on the oxide layer;
a plurality of semiconductor devices formed in the second substrate; and
a plurality of trenches formed in the second substrate and filled with an insulation material, wherein the trenches are separated from each other and one of the trenches surrounds one of the semiconductor devices.

2. The semiconductor structure as claimed in claim 1, wherein the first substrate and the second substrate are silicon substrates.

3. The semiconductor structure as claimed in claim 1, wherein the semiconductor device comprises field-effect transistors (FETs) or bipolar junction transistors (BJTs).

4. The semiconductor structure as claimed in claim 1, wherein the trenches are only filled with the insulation material.

5. A semiconductor structure, comprising:
a first substrate;
an oxide layer formed on the first substrate;
a second substrate formed on the oxide layer;
a plurality of semiconductor devices formed in the second substrate;
a plurality of first trenches formed in the second substrate and filled with an insulation material, wherein the first trenches are separated from each other and one of the first trenches surrounds one of the semiconductor devices;
a contact window formed in the second substrate and extending through the oxide layer, and connected to the first substrate, wherein the contact window is filled with a conductive material; and
a third trench formed in the second substrate and filled with the insulation material, wherein the third trench surrounds the contact window.

6. The semiconductor structure as claimed in claim 5, wherein the first substrate and the second substrate are silicon substrates.

7. The semiconductor structure as claimed in claim 5, wherein the semiconductor device comprises field-effect transistors (FETs) or bipolar junction transistors (BJTs).

8. The semiconductor structure as claimed in claim 5, wherein the first trenches and the third trench are only filled with the insulation material.

9. The semiconductor structure as claimed in claim 5, wherein the contact window has greater width than those of the first trenches and the third trench.

10. The semiconductor structure as claimed in claim 5, wherein the first trenches have the same width as that of the third trench.

11. The semiconductor structure as claimed in claim 5, wherein the first trenches are separated from the third trench.

12. The semiconductor structure as claimed in claim 5, wherein the first trenches partially overlap the third trench.

13. A method for fabricating a semiconductor structure, comprising:
providing a silicon-on-insulator (SOI) structure comprising a first silicon substrate, an oxide layer and a second silicon substrate, wherein the oxide layer is formed on the first silicon substrate and the second silicon substrate is formed on the oxide layer;
forming a plurality of first trenches, a second trench having sidewalls and a bottom and a third trench in the second silicon substrate, wherein the first trenches are separated from each other and the third trench surrounds the second trench;
forming an insulation material on the second silicon substrate to fill the first trenches and the third trench and a part of the second trench;
etching the second trench using the insulation material as a mask to extend through the oxide layer to connect to the first silicon substrate; and
filling a conductive material in the second trench to electrically connect to the first silicon substrate.

14. The method for fabricating a semiconductor structure as claimed in claim 13, wherein the second trench has greater width than those of the first trenches and the third trench.

15. The method for fabricating a semiconductor structure as claimed in claim 13, wherein the first trenches have the same width as that of the third trench.

16. The method for fabricating a semiconductor structure as claimed in claim 13, wherein the first trenches are separated from the third trench.

17. The method for fabricating a semiconductor structure as claimed in claim 13, wherein the first trenches partially overlap the third trench.

18. The method for fabricating a semiconductor structure as claimed in claim 13, wherein only the insulation material fills the first trenches and the third trench.

19. The method for fabricating a semiconductor structure as claimed in claim 13, wherein the insulation material fills on the sidewalls and the bottom of the second trench.

20. The method for fabricating a semiconductor structure as claimed in claim 13, further comprising forming a patterned photoresist layer on the insulation material and etching the second trench using the patterned photoresist layer as a mask to extend through the oxide layer to connect to the first silicon substrate.
